(19) United States
(12) Patent Application Publication
(10) Pub. No.: US 2015/0235678 A1
(43) Pub. Date: Aug. 20, 2015

(54) ADAPTIVE CONTROL METHOD BASED ON INPUT CLOCK AND RELATED ADAPTIVE CONTROLLED APPARATUS

(71) Applicant: Piecemakers Technology, Inc., Hsinchu City (TW)

(72) Inventors: Tah-Kang Joseph Ting, Taipei City (TW); Li-Chin Tien, Hsinchu City (TW)

(21) Appl. No.: 14/623,511

(22) Filed: Feb. 17, 2015

(30) Foreign Application Priority Data
Feb. 20, 2014 (TW) 103105734

(51) Int. Cl. G11C 7/08; G11C 7/22

(52) U.S. Cl. CPC G11C 7/08; G11C 7/222

(57) ABSTRACT

An adaptive control method based on an input clock includes: performing a read process according to the input clock; receiving a read command; receiving a data signal via a data line according to the read command; enabling an amplifier element according to at least the input clock; and utilizing the amplifier element to amplify the data signal.

### BACKGROUND OF THE INVENTION

1. Field of the Invention

The present invention relates to a control technique, and more particularly, to an adaptive control method and related device for controlling a sensing amplifier based on an input clock.

2. Description of the Prior Art

Read procedures of storage devices (e.g. dynamic random access memory (DRAM) or static random access memory (SRAM)) are limited by the timing required for signal transmission. Examples are shown in FIG. 1 and FIG. 2. FIG. 1 illustrates a portion of a conventional read unit 100 architecture. FIG. 2 illustrates some signals of the conventional read unit 100. Each time the storage device 100 receives a read command Rd, it takes time tYS from a rising edge of an input clock CK to selecting a proper Y switch 110 by a selection signal YS0. After the Y switch 110 is conductive, signals from the data lines (each Y switch is responsible for data of two bits, and four switches are required to control four data lines DL, DL−, DL′ and DL′−, which are respectively the complementary signals of two bits) through the Y switch 110 require time tYS2DLSA until the signals are high enough to be correctly recognized and amplified by a sense amplifier 120. An amplifier enablement signal SA_EN enables the sensing amplifier 120 to amplify the signals on the data lines (for ease of explanation, only operations of data lines DL and DL− will be explained). The time required to form an internal transmission signal internal_IO from the sensing amplifier to an internal buffer (not shown) of the read unit 100 is tDLSA2DQBUF. Finally, according to an output indication signal CLKOE, the read data signal is transmitted to a driver (off chip driver, not shown) outside the chip to form an output signal Data_pin, which takes time tOCD. Hence, the time required by the read procedure of the storage device will be a sum of times required by the above-mentioned four procedures, which is: tYS+tYS2DLSA+tDLSA2IOBUF+tOCD.

Times tYS, tDLSA2DQBUF and tOCD cannot be shortened due to certain limitations of design. Time tYS2DLSA cannot be shortened because it is importance to ensure that input differential signals have enough time to develop from zero level to a proper differential level before being processed by the sensing amplifier 120. Hence, after the Y switch receives the signal, it needs to wait a default time (i.e. tYS2DLSA) before enabling the sensing amplifier. For a faster read unit, which operates with a faster input clock and shorter clock period, a much shorter time is taken to develop the signals from zero level to a proper differential level suitable for the sensing amplifier 110. That is, the time needed by waiting to receive the signals to enabling the sensing amplifier 110 could be shorter than the default time. If the conventional read unit still enables the sensing amplifier after the default time expires, the process time will be wasted and the overall performance will be degraded.

### SUMMARY OF THE INVENTION

To address the above-mentioned problem, the present invention provides an adaptive control technique based on an input clock, which selectively controls enablement time of a sensing amplifier based on the input clock to improve the overall operating speed.

According to one exemplary embodiment of the present invention, an adaptive control method based on an input clock is provided. The adaptive control method comprises: performing a read procedure according to the input clock; receiving a read command; receiving a data signal via a data line according to the read command; enabling an amplifying unit according to at least the input clock; and utilizing the amplifying unit to amplify the data signal.

According to one exemplary embodiment of the present invention, an adaptive control device is provided. The adaptive control device comprises: a read unit, an amplifying unit and a control circuit. The read unit is employed for receiving an input clock, and performing a read procedure according to the input clock. The control circuit is coupled to the amplifying unit and the read unit, and employed for receiving a read command and controlling the read unit to receive a data signal via a data line according to the read command, and enabling the amplifying unit according to the input clock to utilize the amplifying unit to amplify the data signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a portion of a conventional read unit architecture.

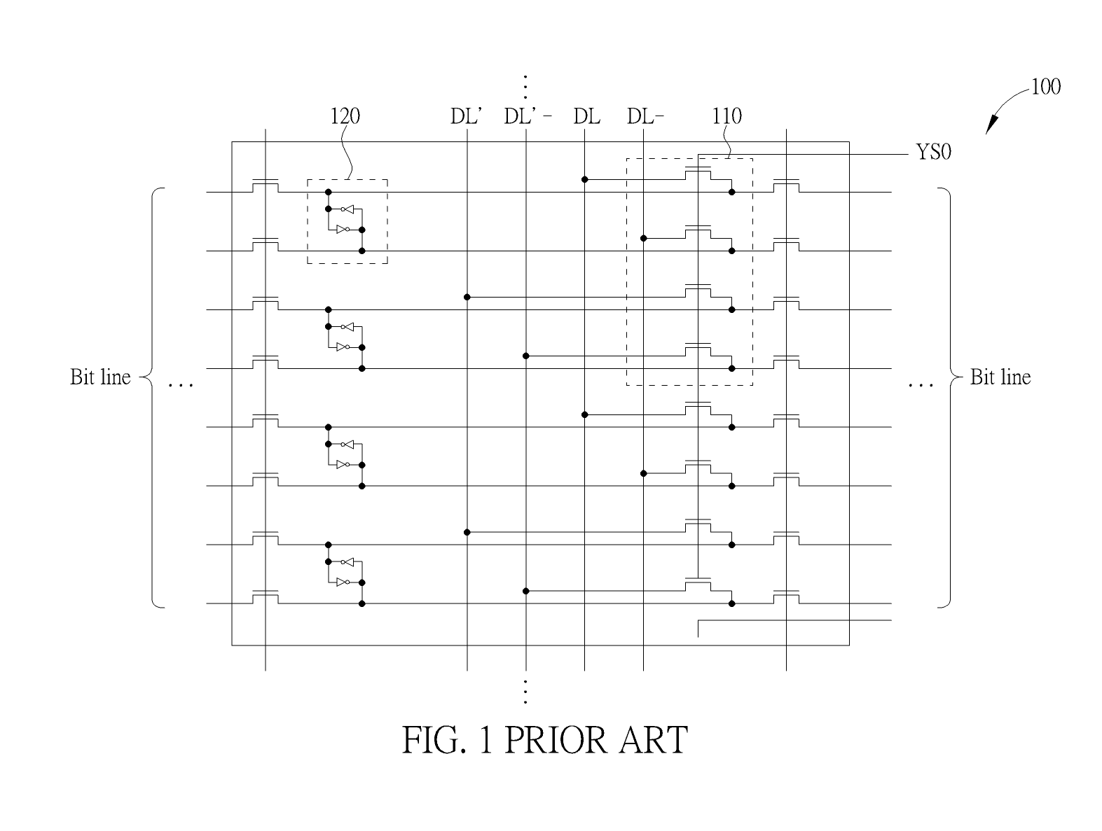

FIG. 2 illustrates some signals of a conventional read unit.

FIG. 3 illustrates a schematic diagram of an adaptive control device according to one exemplary embodiment of the present invention.

FIG. 4 illustrates some signals of the adaptive control device according to a first exemplary embodiment of the present invention.

FIG. 5 illustrates some signals of the adaptive control device according to a second exemplary embodiment of the present invention.

FIG. 6 illustrates some signals of the adaptive control device according to a third exemplary embodiment of the present invention.

FIG. 7 illustrates some signals of the adaptive control device according to a fourth exemplary embodiment of the present invention.

FIG. 8 illustrates some signals of the adaptive control device according to a fifth exemplary embodiment of the present invention.

FIG. 9 illustrates a schematic diagram of an adaptive control device according to another exemplary embodiment of the present invention.

### DETAILED DESCRIPTION

Certain terms are used throughout the following descriptions and claims to refer to particular system components. As one skilled in the art will appreciate, manufacturers may refer to a component by different names. This document does not intend to distinguish between components that differ in name but not differ in functionality. In the following discussion and in the claims, the terms “include”, “including”, “comprise”, and “comprising” are used in an open-ended fashion, and thus should be interpreted to mean “including, but not limited to . . . ” The terms “couple” and “coupled” are intended to mean either an indirect or a direct electrical connection. Thus, if a first device couples to a second device, that connection may be through a direct electrical connection, or through an indirect electrical connection via other devices and connections.

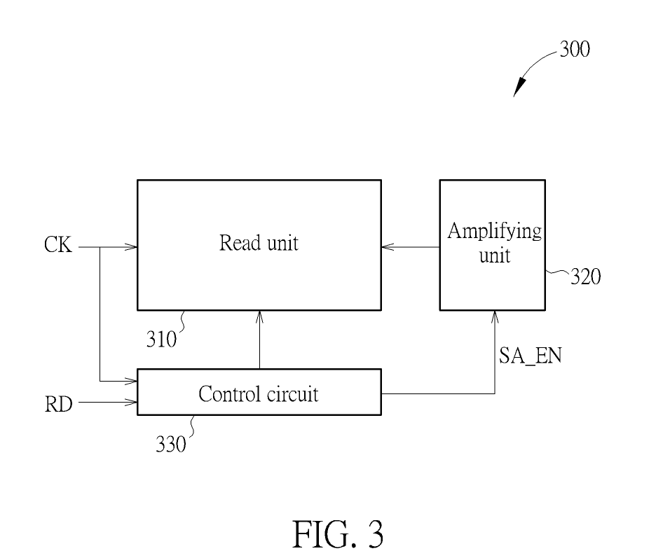

FIG. 3 illustrates a schematic diagram of an adaptive control device 300 implemented according to one exemplary embodiment of the present invention. The adaptive control device 300 comprises: a read unit 310, an amplifying unit 320 and a control circuit 330. The read unit 310 is employed for receiving an input clock CK, and performing a read procedure according to the input clock CK. The control circuit 330 is coupled to the amplifying unit 320 and the read unit 310, and employed for receiving a read command RD, and according to the read command RD, controlling the read unit 310 to receive a data signal via data lines DL and DL−. Subsequently, the control circuit 330 enables the amplifying unit 320 according to the input clock CK. The amplifying unit 320 is further employed for amplifying the data signal. Note that, in this embodiment, after the control circuit 330 receives the read command RD, the control circuit 330 enables the amplifying unit 320 according to a rising edge of the input clock CK to amplify the data signal on the data lines DL and DL−. According to various embodiments of the present invention, it is feasible to use a falling edge of the input clock CK for the purpose of enabling the amplifying unit 320. As long as any design uses the input clock CK to enable the amplifying unit 320, this falls within the scope of the invention. For example, in one embodiment, the control circuit 330 could be implemented with a lock unit (e.g. a phase locked loop, PLL) or a delay lock unit (e.g. delay locked loop, DLL). The control circuit 330 could lock to a frequency of the input clock CK, and generate an adaptive delay time that is directly proportional to a period of the input clock CK according to the frequency of the input clock CK. After the adaptive control device 300 receives the read command Rd, the amplifying unit 320 will be enabled when the adaptive delay time expires. In another embodiment, if the frequency of the input clock CK falls within a predetermined range, after receiving the read command Rd, the adaptive control device 300 will enable the amplifying unit 320 once a default delay time expires. If the frequency of the input clock CK falls outside the predetermined range, the adaptive control device 300 will generate the adaptive delay time that is directly proportional to the period of the input clock CK. After the read command Rd is received, the amplifying unit 320 will be enabled when the adaptive delay time expires. The above-mentioned implementations all fall within the scope of the present invention.

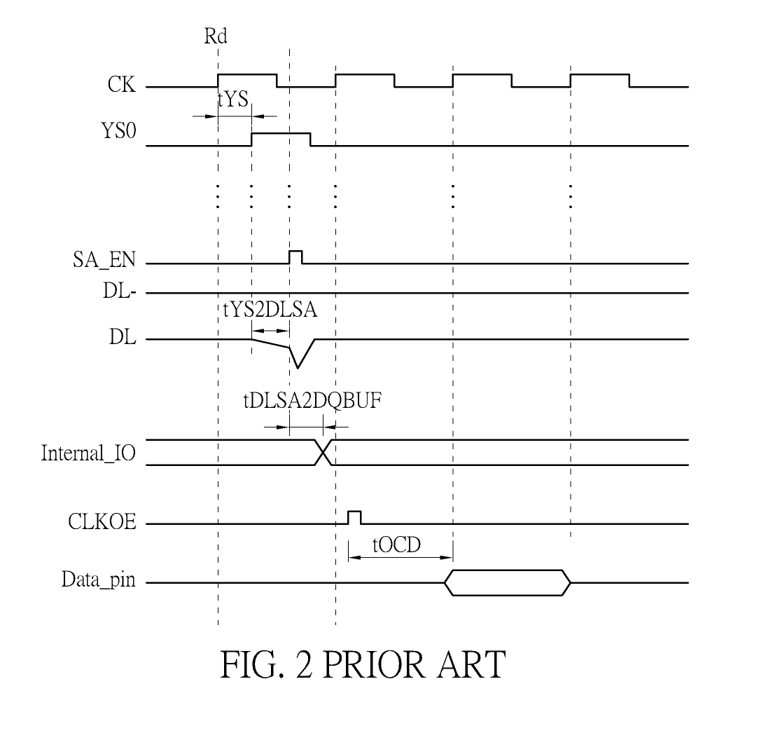

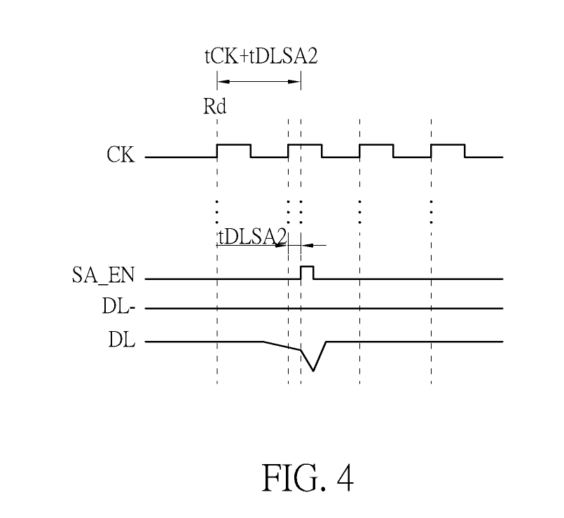

FIG. 4 illustrates operations and principles of the adaptive control device 300 for further details. FIG. 4 illustrates some signals of the adaptive control device 300 according to a first exemplary embodiment of the present invention. After the adaptive control device 300 receives the read command Rd, the rising edge of the input clock CK will trigger and select one Y switch of the read unit 310 for transmission. Enablement of the amplifying unit 320 (which serves as a sensing amplifier here) of the adaptive control device 300 is controlled by the rising edge of the input clock CK. Thus, the required time from receiving the read command Rd to amplifying the signal by the amplifying unit 320 would be tCK+tDLSA2. In this embodiment, tCK is the period of the input clock CK, while tDLSA2 is default delay time and subsequent to the second rising edge after the read command Rd. In the conventional art shown by FIG. 2, the required time from receiving the read command Rd to amplifying the signal by the amplifying unit 320 would be tYS+tYS2dlsa, but in this embodiment the required time would be tCK+tDLSA2. In other words, the required time becomes a period of time that is in positive correlation with the input clock, instead of a constant period of time. Hence, the adaptive control device 300 may process the read command faster than the conventional art when receiving high-speed clocks.

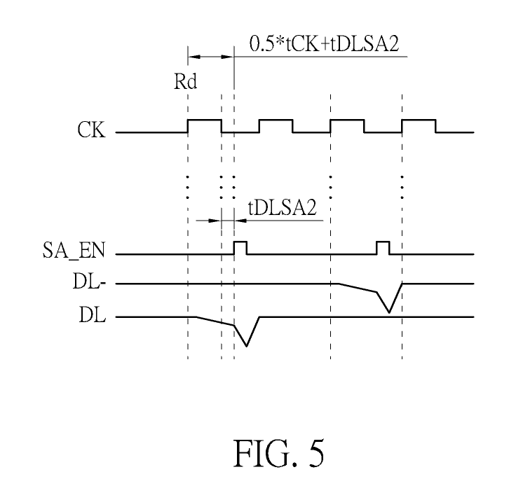

Note that the period of time that is in positive correlation with the input clock is not limited to one period tCK of the input clock. For example, it could be related to 0.5 period, 1.5 periods, 2 periods or the like. The operation of the adaptive control device 300 may lead to the result as shown in FIG. 5. FIG. 5 illustrates some signals of the adaptive control device 300 according to a second exemplary embodiment of the present invention. After the adaptive control device 300 receives the read command Rd, the rising edge of the input clock CK will trigger and select one Y switch of the read unit 310 for transmission. Enablement of the amplifying unit 320 (which serves as a sensing amplifier here) of the adaptive control device 300 is controlled by a falling edge of the input clock CK at a half period subsequent to triggering the read unit 310. Thus, the required time from receiving the read command Rd to amplifying the signal by the amplifying unit 320 would be 0.5*tCK+tDLSA2. In this embodiment, tCK is the period of the input clock CK, while tDLSA2 is default delay time and subsequent to the first falling edge after the read command Rd. In the conventional art shown by FIG. 2, the required time from receiving the read command Rd to amplifying the signal by the amplifying unit 320 would be tYS+tYS2dlsa, but in this embodiment the required time would be 0.5*tCK+tDLSA2. In other words, the required time becomes a period of time that is in positive correlation with the input clock, instead of a constant period of time. Hence, the adaptive control device 300 may process the read command faster than the conventional art when receiving high-speed clocks.

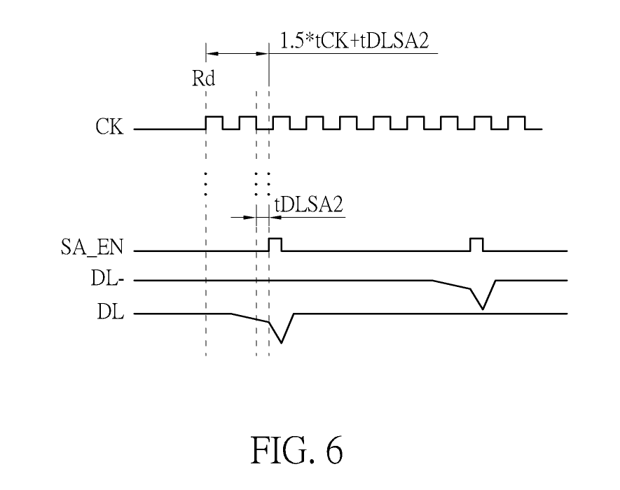

The operation of the adaptive control device 300 could also lead to the result shown in FIG. 6. FIG. 6 illustrates some signals of the adaptive control device 300 according to a third exemplary embodiment of the present invention. After the adaptive control device 300 receives the read command Rd, the rising edge of the input clock CK will trigger and select one Y switch of the read unit 310 for transmission. Enablement of the amplifying unit 320 (which serves as a sensing amplifier here) of the adaptive control device 300 is controlled by a second falling edge of the input clock CK at one and a half periods subsequent to triggering the read unit 310. Thus, the required time from receiving the read command Rd to amplifying the signal by the amplifying unit 320 would be 1.5*tCK+tDLSA2. In this embodiment, tCK is the period of the input clock CK, while tDLSA2 is default delay time and subsequent to the second falling edge after the read command Rd. In the conventional art shown by FIG. 2, the required time from receiving the read command Rd to amplifying the signal by the amplifying unit 320 would be tYS+tYS2dlsa, but in this embodiment the required time would be 1.5*tCK+tDLSA2. In other words, the required time becomes a period of time that is in positive correlation with the input clock, instead of a constant period of time. Hence, the adaptive control device 300 may process the read command faster than the conventional art when receiving high-speed clocks.

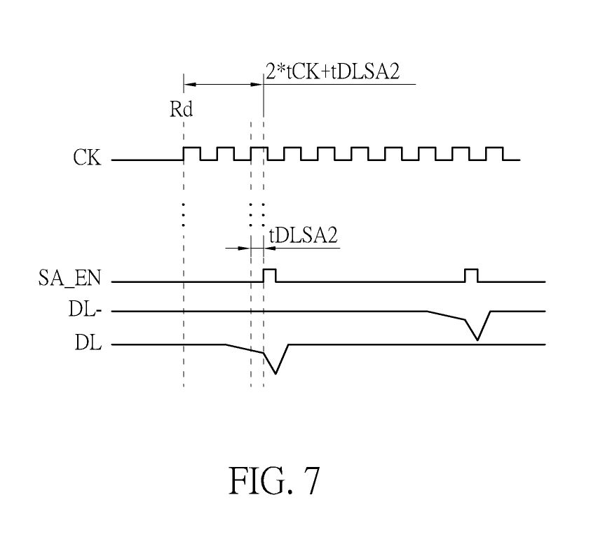

The operation of the adaptive control device 300 may lead to the result as shown in FIG. 7. FIG. 7 illustrates some signals of the adaptive control device 300 according to a fourth exemplary embodiment of the present invention. After the adaptive control device 300 receives the read command Rd, the rising edge of the input clock CK will trigger and select one Y switch of the read unit 310 for transmission. Enablement of the amplifying unit 320 (which serves as a sensing amplifier here) of the adaptive control device 300 is controlled by a second rising edge of the input clock CK at two periods subsequent to triggering the read unit 310. Thus, the required time from receiving the read command Rd to amplifying the signal by the amplifying unit 320 would be 2*tCK+tDLSA2. In this embodiment, tCK is the period of the input clock CK, while tDLSA2 is default delay time and subsequent to the second rising edge after the read command Rd. In the conventional art shown by FIG. 2, the required time from receiving the read command Rd to amplifying the signal by the amplifying unit 320 would be tYS+tYS2dlsa, but in this embodiment the required time would be 2*tCK+tDLSA2. In other words, the required time becomes a period of time that is in positive correlation with the input clock, instead of a constant period of time. Hence, the adaptive control device 300 may process the read command faster than the conventional art when receiving high-speed clocks.

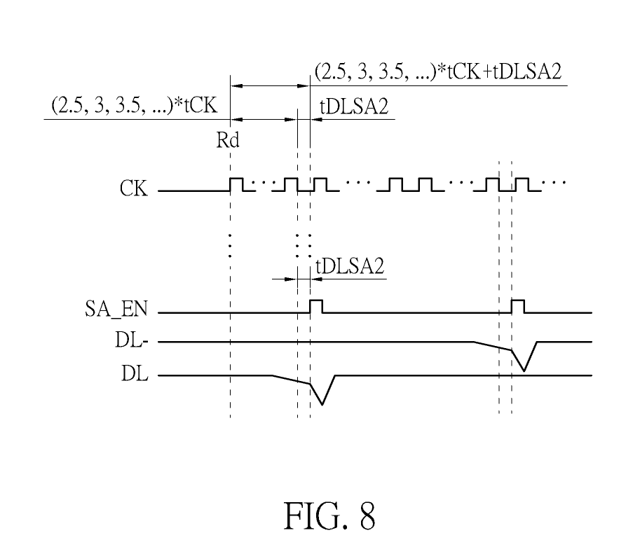

It can be understood from the above embodiments that when the control circuit 330 receives the read command RD, it can enable the amplifying unit 320 at a rising edge or a falling edge after multiples of a half period of the input clock CK. For example, the control circuit 330 could enable the amplifying unit 320 according to an edge (rising or falling) at 2.5, 3, or 3.5 periods of the input clock CK, as shown in FIG. 8.

FIG. 8 illustrates some signals of the adaptive control device 300 according to a fifth exemplary embodiment of the present invention. After the adaptive control device 300 receives the read command Rd, the rising edge of the input clock CK will trigger and select one Y switch of the read unit 310 for transmission. The enablement of the amplifying unit 320 (which serves as a sensing amplifier) of the adaptive control device 300 could be controlled by signal transition (i.e. the rising edge or the falling edge) at multiples (2.5, 3, or 3.5) of the period after the input clock CK triggers the read unit 310. Thus, the required time from receiving the read command Rd to amplifying the signal by the amplifying unit 320 would be (2.5, 3, 3.5, . . . )*tCK+tDLSA2. In this embodiment, tCK is the period of the input clock CK, while tDLSA2 is default delay time and fixedly at the occurrence of signal transition at selected multiples of the period after the read command Rd. In the conventional art shown by FIG. 2, the required time from receiving the read command Rd to amplifying the signal by the amplifying unit 320 would be tYS+tYS2dlsa, but in this embodiment the required time would be (2.5, 3, 3.5, . . . )*tCK+tDLSA2. In other words, the required time becomes a period of time that is in positive correlation with the input clock, instead of a constant period of time. Hence, the adaptive control device 300 may process the read command faster than the conventional art when receiving high-speed clocks.

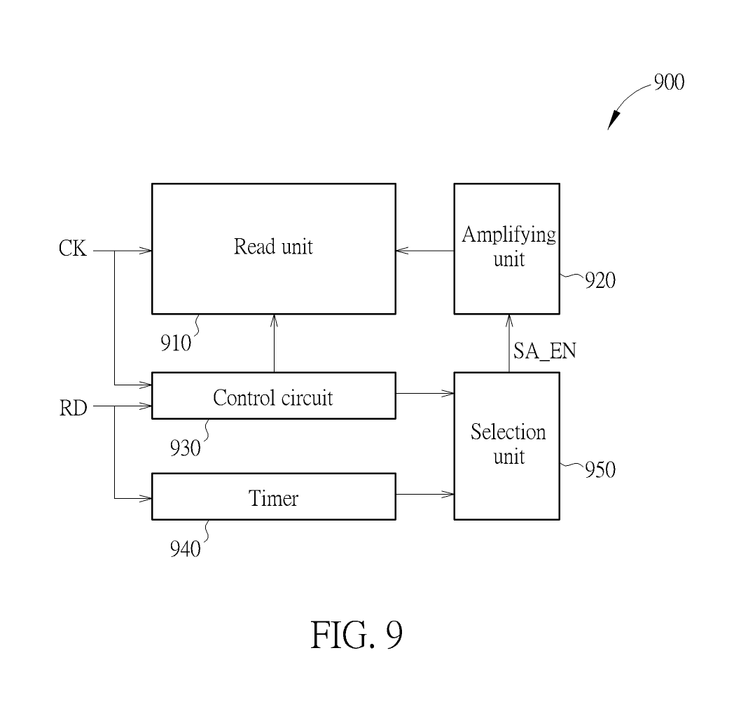

FIG. 9 illustrates a schematic diagram of an adaptive control device 900 according to another exemplary embodiment of the present invention. The adaptive control device 900 comprises: a read unit 910, an amplifying unit 920, a control circuit 930, a timer 940 and a selection unit 950. Functionalities and architecture of the read unit 910, the amplifying unit 920, and the control circuit 930 are substantially identical to those of the read unit 310, the amplifying unit 320, and the control circuit 330 of FIG. 3. Hence, the detailed descriptions of the read unit 910, the amplifying unit 920 and the control circuit 930 are omitted here. The timer 940 is employed for providing a default delay time to the selection unit 950. After receiving the read command Rd, the selection unit 950 generates an amplifying unit enablement signal SA_EN according to the default delay time or the input clock CK to enable the amplifying unit 920. The selection unit 950 can be implemented with a simple OR logic gate, a phase/frequency detector or any other similar circuitry. Note that, when the frequency of the input clock CK is lower, the adaptive control device 900 enables the amplifying unit 920 through the path from the timer 940 to the selection unit 950. Similar to the conventional art, by properly choosing the default delay time, the selection unit 950 waits the time tYS+tYS2DLSA to generate the amplifier unit enablement signal SA_EN to enable the amplifying unit 920 after the timer 940 receives the read command Rd. What is different from the conventional art is that once the frequency of the input clock CK is higher than a threshold, the amplifying unit 820 is enabled through the path from the control circuit 930 to the selection unit 950 to achieve a better performance. Hence, the adaptive control device 900 uses different processing paths according to different input clocks so that the performance can be improved.

In conclusion, the present invention provides an adaptive control method based on an input clock and related apparatus. The timing of enabling the sensing amplifier may be determined according to the period of the input clock. Hence, the performance of the present invention can be improved as the frequency of the input clock increases.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An adaptive control method based on an input clock, comprising:
performing a read procedure according to the input clock;
receiving a read command;
receiving a data signal via a data line according to the read command;
enabling an amplifying unit according to at least the input clock; and
utilizing the amplifying unit to amplify the data signal.

2. The adaptive control method of claim 1, wherein the step of enabling the amplifying unit according to at least the input clock comprises:
after receiving the read command, enabling the amplifying unit according to a rising edge of the input clock of the read command.

3. The adaptive control method of claim 1, wherein the step of enabling the amplifying unit according to at least the input clock comprises:
enabling the amplifying unit according to a next falling edge of the input clock of the read command which is half period after a rising edge of the input clock of the read command.

4. The adaptive control method of claim 1, wherein the step of enabling the amplifying unit according to at least the input clock comprises:
enabling the amplifying unit according to a next rising edge of the input clock which is one clock period of the input clock after a rising edge of the input clock of the read command.

5. The adaptive control method of claim 1, wherein the step of enabling the amplifying unit according to at least the input clock comprises:
enabling the amplifying unit according to a falling edge of the input clock at 1.5 periods after a rising edge of the input clock of the read command.

6. The adaptive control method of claim 1, wherein the step of enabling the amplifying unit according to at least the input clock comprises:
enabling the amplifying unit according to a rising edge of the input clock at two periods after a rising edge of the input clock of the read command.

7. The adaptive control method of claim 1, wherein the step of enabling the amplifying unit according to at least the input clock comprises:
enabling the amplifying unit according to a rising edge of the input clock at n-th clock period after a rising edge of the input clock of the read command or a falling edge of the n-th clock which is at (n+0.5) clock period after a rising edge of the input clock of the read command, where n is an integer.

8. The adaptive control method of claim 1, wherein the step of enabling the amplifying unit according to at least the input clock comprises:
obtaining a delay time according to a period of the input clock; and
after receiving the read command, enabling the amplifying unit according to the delay time.

9. The adaptive control method of claim 1, further comprising:
receiving a default delay time;
and the step of enabling the amplifying unit according to at least the input clock comprises:
after receiving the read command, enabling the amplifying unit selectively according to the default delay time or the input clock.

10. The adaptive control method of claim 1, further comprising:
detecting a period of the input clock;
generating an adaptive delay time that is directly proportional to the period; and
the step of enabling the amplifying unit according to at least the input clock comprises:
after receiving the read command, enabling the amplifying unit according to the adaptive delay time.

11. An adaptive control device, comprising:
a read unit, for receiving an input clock, and performing a read procedure according to the input clock;
an amplifying unit; and
a control circuit, coupled to the amplifying unit and the read unit, for receiving a read command, and controlling the read unit to receive a data signal via a data line according to the read command, and enabling the amplifying unit according to the input clock to utilize the amplifying unit to amplify the data signal.

12. The adaptive control device of claim 11, wherein the control circuit enables the amplifying unit according to a rising edge of the input clock after receiving the read command.

13. The adaptive control device of claim 11, wherein the control circuit enables the amplifying unit according to a falling edge of the input clock at a half period of the input clock after receiving the read command.

14. The adaptive control device of claim 11, wherein the control circuit enables the amplifying unit according to a rising edge of the input clock at one period of the input clock after receiving the read command.

15. The adaptive control device of claim 11, wherein the control circuit enables the amplifying unit according to a falling edge of the input clock at one and a half periods of the input clock after receiving the read command.

16. The adaptive control device of claim 11, wherein the control circuit enables the amplifying unit according to a rising edge of the input clock at two periods of the input clock after receiving the read command.

17. The adaptive control device of claim 11, wherein the control circuit enables the amplifying unit according to a rising edge or a falling edge of the input clock at half period multiples of the input clock after receiving the read command.

18. The adaptive control device of claim 11, wherein the control circuit obtains a delay time according to a period of the input clock and enables the amplifying unit according to the delay time.

19. The adaptive control device of claim 11, further comprising:
a selection unit, coupled to the timer, for enabling the amplifying unit selectively according to a default delay time or the input clock after receiving the read command.

20. The adaptive control device of claim 11, wherein the control circuit further comprises:
a lock unit, for detecting a period of the input clock and generating an adaptive delay time that is directly proportional to the period; and
a selection unit, coupled to the lock unit, for enabling the amplifying unit according to the adaptive delay time after receiving the read command.

21. The adaptive control device of claim 20, wherein the lock unit is a phase locked loop (PLL) or a delay locked loop (DLL).
